(19) United States
(12) Patent Application Publication
(10) Pub. No.: US 2002/0172017 A1
(43) Pub. Date: Nov. 21, 2002

(54) Functional enclosure for a personal electronic device

(76) Inventors: Thomas J. Tarnowski, Midland, MI (US); Tor A. Alden, Basking Ridge, NJ (US); Shaoghui Qiu, Minneapolis, MN (US); Brett R. Johnson, St. Paul, MN (US); James A. Wilson, Minneapolis, MN (US)

Correspondence Address: THE DOW CHEMICAL COMPANY, INTELLECTUAL PROPERTY SECTION, P. O. BOX 1967, MIDLAND, MI, 48641-1967, US

(21) Appl. No.: 09/862,020

(22) Filed: May 21, 2001

(51) Int. Cl. H05K 5/00; H05K 5/04; H05K 5/06

(52) U.S. Cl. 361/730

(57) ABSTRACT

Disclosed is a configurable housing for a personal electronic device having multiple operating modes wherein the configuration of the housing determines the operating mode of the personal electronic device. Moreover, each configuration is well suited and easy to use for the selected operating mode.

### FIELD OF THE INVENTION

The present invention relates to a configurable housing for a personal electronic device.

### BACKGROUND OF THE INVENTION

Personal electronic devices, such as cell phones, pagers, personal digital assistants (PDAs), gaming devices, electronic music players, voice recorders, global positioning systems (GPS) and the like, have become common place in today's society. These personal electronic devices have found utility in all aspects of life including personal and/or professional activities. In fact, it's common for a person to possess two or more such personal electronic devices, for example it's not unusual to see a teenager or a stay at home parent or a business professional with a cell phone, a PDA, a gaming device and/or an electronic music player.

While any one of these personal electronic devices can usually be carried conveniently by a person, either on a belt, in a pocket or hand bag, carrying multiple electronic devices becomes inconvenient at best, if not burdensome. Attempts to combine functions, or operating modes, into a single personal electronic device have met with limited functional, if not technical, success. For example, playing an electronic game using the keys of a keyboard, especially very small keys such as found on some personal electronic devices, can be difficult, frustrating and at the very least unenjoyable.

### SUMMARY OF THE INVENTION

The object of this invention is to present a configurable housing for a personal electronic device. A further object of this invention is to present a configurable housing for a personal electronic device having multiple operating modes wherein each configuration is well suited and easy to use for a particular operating mode. An object of this invention is also to present a configurable housing for a personal electronic device having multiple operating modes wherein the configuration of the housing determines the operating mode of the personal electronic device.

In a preferred object of this invention, one or more configurable section(s) is detachable/attachable to the main body.

A more preferred object of this invention is a first personal electronic device having a configurable housing having a first set of one or more detachable/attachable configurable section(s) attached to a first main body, said first personal electronic device having more than one mode of operation, and a second personal electronic device having a second configurable housing having a second set of detachable/attachable configurable section(s) attached to a second main body, said second personal electronic device having more than one mode of operation, wherein the operating modes for the first personal electronic device are the same, partially the same or different than the operating modes for the second personal electronic device, preferably, said first main body is the same as the second main body.

A further object of this invention is to present a method to prepare a configurable housing for a personal electronic device.

The objectives of the invention are achieved by a housing comprising a main body and one or more configurable sections.

### BRIEF DESCRIPTION OF THE DRAWINGS

Below the invention will be described in more detail with reference to the preferred embodiments shown as examples and to the enclosed figures, in which:

FIG. 1 shows schematically the front view of a configurable housing with 2 configurable sections in a first configuration;

FIG. 2 shows schematically the bottom edge of the configurable housing of FIG. 1;

FIG. 3 shows schematically the back view of the configurable housing of FIG. 1;

FIG. 4 shows in a perspective view the configurable housing of FIG. 1;

FIG. 5 shows in a perspective view the configurable housing of FIG. 1 in a second configuration; and

FIG. 6 shows in a perspective view the configurable housing of FIG. 1 in a third configuration.

### DETAILED DESCRIPTION OF THE EMBODIMENTS

The configurable housing of the present invention comprises one or more configurable sections. As used herein, configurable section is defined to mean a section that can assume more than one spatial location in relationship to the main body of the housing. Any means to reconfigure a section versus the main body of the housing may be used, for example, rotating, sliding, bending, flexing, twisting, folding (with or without hinges), disconnecting, disconnecting/reconnecting in a different spatial location, and the like. The number of configurable sections is dependent upon several considerations, for example, the number and types of operating modes for the personal electronic device or how many hands are require for a particular mode, i.e., two hands (e.g., gaming device), one hand (e.g., cell phone) or no hands (e.g., desktop PDA), if the personal electronic device is to be worn (e.g., around the neck or wrist) or affixed to clothing (e.g., on a belt or purse strap), etc. There is no limit for the number of configurable sections, but generally there are between 1 to 10, preferably 1 to 5, more preferably 2 to 5 and most preferably 2 to 4 configurable sections.

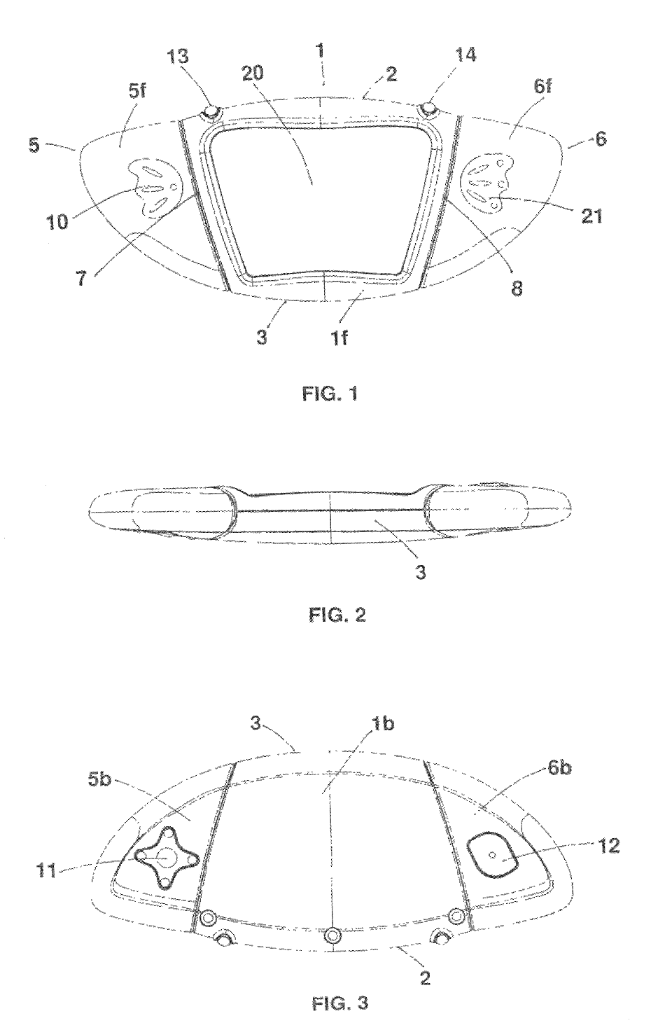

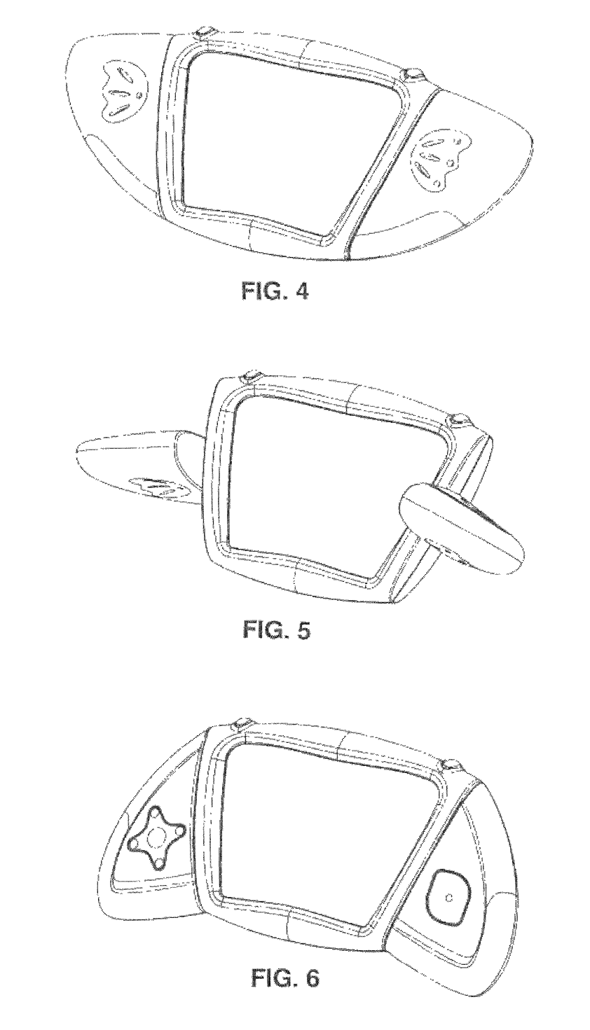

FIG. 1 and FIG. 3 show schematically the front and back surfaces of a configurable housing with main body 1 having a front surface if, a back surface 1b, a top edge 2 and a bottom edge 3, a first 5 and a second 6 configurable section, each having a front surface 5f and 6f and a back surface 5b and 6b. FIG. 4 shows in a perspective view the configurable housing of FIG. 1. FIG. 5 shows in a perspective view the configurable housing of FIG. 1 with the first and second configurable sections 5 and 6 reconfigured 90° from their first configuration. FIG. 6 shows in a perspective view the configurable housing of FIG. 1 with the first and second configurable sections 5 and 6 reconfigured 180° from their first configuration with the back surfaces of the first and second configurable sections 5b and 6b showing. Reconfiguration can be achieved by rotating the first and second sections 5 and 6 at points 7 and 8, respectively, while remaining attached to the main body or detaching them from the main body, rotating and reattaching them.

Preferably, the main body is capable of accepting one or more configurable section that is detachable and attachable. Any means for detaching/attaching or connecting such configurable sections is within the scope of this invention as long as the means provides for a way to (1) connect the detachable/attachable section to the main body, which allows for the detachable/attachable section to assume one or more configuration and the personal electronic device two or more modes of operation, for example, snap fits, flexible connectors, rotational connectors, ball and socket connectors, tongue and groove connectors, slip joints, and the like and (2) provides the necessary interface between the detachable/attachable configurable section and the main body to allow operability of the personal electronic device, for example an electronic interface, an inferred interface and the like. Preferably, the detachable/attachable section physically connects to the main body while maintaining the ability to assume more than one spatial location in relationship to the main body.

Preferably, there is a plurality of detachable/attachable configurable sections that can attach interchangeably to one or more main bodies. Different detachable/attachable configurable sections can contain different input and/or output means, which when attached to the main body can result in different modes of operation for the resulting personal electronic device.

For example, a first main body can accept a first set comprising one or more detachable/attachable configurable section(s) producing a first configurable housing for a first personal electronic device with two or more modes of operation. A second main body can accept a second set of one or more detachable/attachable configurable section(s) producing a second configurable housing for a second personal electronic device having two or modes of operation. Preferably, the means to connect the first set of detachable/attachable configurable section(s) and the second set of detachable/attachable configurable section(s) are the same such that each set can interchangeably connect to either the first and second main bodies. The first main body may be the same, i.e., in appearance, functions, electronic capabilities, structure, design, etc., or different, i.e., in appearance, functions, electronic capabilities, structure, design, etc. from the second main body, preferably the first main body is the same as the second main body. The modes of operation for the first personal electronic device with the first configurable housing may be the same, partially the same or different than the modes of operation for the second personal electronic device with the second configurable housing.

A further example is, a first detachable/attachable configurable section (1) comprises a memory/software bay, a second detachable/attachable configurable section (2) comprises a pivoting video camera, a third detachable/attachable configurable section (3) comprises a GPS navigational system, a fourth detachable/attachable configurable section (4) comprises a digital camera, a fifth detachable/attachable configurable section (5) comprises a barcode scanner, a sixth detachable configurable section (6) comprises a connector for docking, a seventh detachable/attachable configurable section (7) comprises a wireless web connection, an eighth detachable/attachable configurable section (8) comprises voice recognition capabilities, a ninth detachable/attachable configurable section (9) comprises a IR receiver and/or transmitter, a tenth detachable/attachable configurable section (10) comprises a MP3 player, an eleventh detachable/attachable configurable section (11) comprises one or more external body sensors, a twelfth detachable/attachable configurable section (12) comprises an altimeter, and the like, wherein each detachable/attachable configurable section can be connected to the same or different main body, individually or in combination of two or more to provide a personal electronic device with two or more operating modes. Combinations of different detachable/attachable configurable sections interchangeably attached to a main body, such as a first main body plus sections (1) and (2), or the first main body plus sections (3) and (4), or the first main body plus sections (5), (6) and (7), or a second main body plus sections (8) and (9), or a third main body plus sections (10), (11) and (12), etc., provide personal electronic devices with different operating modes.

In any functional configuration, or operating mode, the housing will comprise a user interface whereby the user interface comprises one or more input means and one or more indicator means. The configurable housing of the present invention comprises one or more user input means such as, but not limited to, a key pad, a key board, switch(es), button(s), a liquid crystal display (LCD), a stylus, a microphone, voice activation, inferred (IR) receiver, a scanner, a barcode scanner, a thermocouple, a digital camera, a video recorder, a memory/software bay, etc. For example, the configurable housing illustrated in FIG. 1 and FIG. 3 comprises a microphone 10 on the front surface of the first configurable section 5f, a cross-key switch 11 on the back surface of the first configurable section 5b, a push-button switch 12 on the back surface of the second configurable section 6b, a first 13 and a second 14 push-button switches on the top edge 2 of the main body. Additional input means (not shown) are present as needed.

The configurable housing of the present invention comprises one or more user indicator means such as, but not limited to, a LCD, a speaker, light(s), vibration means, a light emitting diode(s) (LED), IR transmitter, etc. For example, the configurable housing illustrated in the FIG. 1 comprises a LCD 20 on the front surface of the main body If and a speaker 21 on the front surface of the second configurable section 6f.

It is understood that an input means in one configuration may be an indicator means in another configuration and vice versa, i.e., a LCD could be a key pad (input means) in a cell phone mode and a video screen (output means) in a game device mode.

Further, the configurable housing may contain other user input or indicator means or functionality not shown in the figures such as an on/off switch, a stylus, an integral antenna, a belt clip, a key ring, an ear piece holder or insertion ports, that can accommodate connectors to connect to other devices such as computers, scanners, fax machines, printers, copiers, ear phones, video players (VCR and/or DVD), digital cameras and the like.

Preferably, the configuration of the housing dictates the mode of operation of the personal electronic device. Further, it is possible to make the push-buttons possess different functions under program control and to dynamically change depending on the mode of operation. Thus, the different input and/or indicator means may have different functions depending on the mode of operation.

The following are examples of modes of operation for the personal electronic device of the present invention: electronic monitoring of natural and/or physiological conditions, storage/display of electronic information, wireless exchange of text and/or audio and/or video information, audio and/or video storage and/or play-back, remote control of electronic devices, GPS navigation, mapping, barcode scanning, gaming, emergency distress signal, record and/or display digital images, and the like.

The configurable housing of the present invention can be made from any suitable material of construction typically used for personal electronic device housings such as one or more metals, one or more plastics or combinations thereof. Plastics include both thermoplastics and thermosets and may be transparent, translucent, opaque or combinations thereof. Examples of suitable plastics are styrene based polymers including homopolymers (i.e., general purpose polystyrene (PS), rubber modified PS, etc.), copolymers (i.e., styrene and acrylonitrile (SAN), styrene and maleic anhydride (SMA), acrylonitrile, butadiene and styrene (ABS) terpolymer, etc.), and alloys (i.e., styrene and polyphenylene oxide (mPPO)); polyolefins including homopolymers (i.e., polyethylene, polypropylene, polybutadiene, etc.), copolymers (ethylene with vinyl acetate (E/VA), acrylic acid (E/AA), methacrylate (E/MA), propylene and diene (EPDM), propylene (EP), etc.) and modified polyolefins (i.e., polyolefin elastomer (POE), thermoplastic polyolefin (TPO), etc.); polyvinyl chloride; polyester resins; polycarbonate (PC) based polymers including homopolymers (i.e., bisphenol-A homopolymer) and blends (PC/ABS, PC/polyester, etc.); acrylics; epoxy resins; urethanes; polyamides; silicones, polyarylsulfides; polyphenylene sulfides; polyarylethers; polymethacrylates; polyacrylates; polyvinyl acetates; and the like. Preferred thermoplastics are PC and PC/ABS blends.

Plastic resins may also contain one or more additives that are commonly used in polymers of this type. Preferred additives of this type include, but are not limited to: pigments, dyes, fillers, reinforcements, ignition resistant additives, stabilizers, colorants, antioxidants, antistats, flow enhancers, mold releases, nucleating agents, etc. Preferred examples of fillers and or reinforcements are glass (fiber, bead, mat, flake, etc.); wollastonite; clay; mica; carbon (carbon fibers, carbon black, conductive carbon, etc.); talc; calcium carbonate; metals; and the like. Additionally, ignition resistance additives, such as, but not limited to halogenated hydrocarbons, halogenated carbonate oligomers, halogenated diglycidyl ethers, organophosphorous compounds, fluorinated olefins, antimony oxide and metal salts of aromatic sulfur, or a mixture thereof may be used. Further, compounds which stabilize polymer blend compositions against degradation caused by, but not limited to heat, light, and oxygen, or a mixture thereof may be used.

The configurable housing of the present invention can be made from any suitable fabricating process depending on the material of choice, for example stamping, machining, die casting, thixotropic metal injection molding, and the like for metals or injection molding (gas assist, structural foam, etc.), thermoforming, compression molding, blow molding, vacuum molding, transfer molding, hand lay-up techniques, spray-up techniques, and the like for plastics.

The configurable housings of the present invention may or may not be painted or some how coated for decorative, aesthetic (i.e., soft touch, luminescence, etc.) or functional (i.e., conductive coating, scratch resistance, etc.) purposes.

The configurable housing of the present invention would be suitable for enclosing personal electronic devices having one or more mode of operation such as found in gaming devices; PDAs; electronic picture frames; clocks, calendars, speaker phones, hand-held digital cameras; electronic music players; voice recorders; radios; optical scanners; wireless cellular communications including but not limited to voice communications (e.g., cell phones), music, images, video, software, data, weather information, clock synchronization signals, global positioning signals, and faxes; and as a remote control (i.e., for controlling televisions, video equipment, stereo components, garage door openers, or home automation systems).

### EXAMPLE

The personal electronic device illustrated in FIG. 4 possess a cell phone configuration/mode, in FIG. 5 a PDA configuration/mode and in FIG. 6 a gaming configuration/mode. Additional push-buttons and/or switches (not shown) may be present for other functions, for example, an on/off switch, a game start switch, a game selection switch, a switch to pause the game or the like. There may be multiple push-buttons and/or switches, each having a single function or one or more push-buttons and/or switches programmed with multiple functions.

With the configurable sections 5 and 6 rotated so the back surfaces 5b and 6b are aligned with the front surface of the main body 1f (FIG. 6) the personal electronic device is configured to operate in a gaming mode. In this mode the cross-key switch 11 has four direction designating portions or contacts and, by depressing any one of the same, it is possible to, for example, move a game character displayed on LCD panel 20 upward or downward or leftward or rightward. In addition, push-button switches 13 and 14 are provided on the top edge of the main body. These push-button switches 13 and 14 are operated when it is necessary to control the game character being displayed on the LCD panel 20 to perform various predetermined actions. For example, when the push-button switch 13 is depressed, the displayed character may appear to jump, or when the pushbutton switch 14 is depressed, the character may appear to throw a stone, or a ball, or launch various other objects. Thus, the cross-key switch 11 is disposed to be operated by the thumb of the left hand, which sandwiches the case 1 in cooperation with the right hand, and the push-button switches 13 and 14 are disposed to be operated by the forefinger of the left and right hands, respectively.

With the configurable sections 5 and 6 rotated 90° to the main body (FIG. 5) the personal electronic device is configured to operate in a PDA mode. The user interface comprises an LCD 20 which functions as a touch sensitive numerical key pad/alphanumeric display and push-buttons 13 and 14 are used to access different applications such as an Phone/Address Book, Calendar, or Calculator modes.

With the configurable sections 5 and 6 rotated so the front surfaces 5f and 6f are aligned with the front surface of the main body (FIG. 4) the personal electronic device is configured to operate in a cell phone mode. The user interface comprises a microphone 10, speaker 21, LCD 20 which functions as a touch sensitive numerical keypad and/or optionally as an alphanumeric display and control keys 13 and 14.

What is claimed is:

1. A configurable housing for a personal electronic device.

2. The configurable housing according to claim 1 comprising a main body and one or more configurable sections.

3. The configurable housing according to claim 1 wherein the personal electronic device has more than one mode of operation.

4. The configurable housing according to claim 3 wherein the configuration of the housing determines the mode of operation of the personal electronic device.

5. The configurable housing according to claim 2, 3 or 4 wherein one or more configurable sections is detachable/attachable to the main body.

6. The detachable/attachable configurable section of claim 5.

7. A means for detaching and attaching the detachable/attachable configurable sections of claim 5 to the main body.

8. The main body of claim 5 capable of accepting one or more detachable/attachable configurable sections.

9. A first configurable housing for a first personal electronic device according to claim 5 having a first set of one or more detachable/attachable configurable section(s) attached to a first main body, said first personal electronic device having more than one mode of operation and a second configurable housing for a second personal electronic device according to claim 5 having a second set of detachable/attachable configurable section(s) attached to a second main body, said second personal electronic device having more than one mode of operation, wherein the operating modes for the first personal electronic device are the same, partially the same or different than the operating modes for the second personal electronic device, and the first main body is the same as the second main body.

10. The configurable housing of claim 3 or 4 wherein the personal electronic device has two or more of the following modes of operation: electronic monitoring of natural and/or physiological conditions, storage/display of electronic information, wireless exchange of text and/or audio and/or video information, audio and/or video storage and/or play-back, remote control of electronic devices, GPS navigation, mapping, barcode scanning, gaming, emergency distress signal, or record and/or display digital images.

11. The configurable housing of claim 5 wherein the personal electronic device has two or more of the following modes of operation: electronic monitoring of natural and/or physiological conditions, storage/display of electronic information, wireless exchange of text and/or audio and/or video information, audio and/or video storage and/or play-back, remote control of electronic devices, GPS navigation, mapping, barcode scanning, gaming, emergency distress signal, or record and/or display digital images.

12. The configurable housing of claim 1 wherein the personal electronic device has a liquid crystal display and one or more of the following input and/or indicator means: digital camera, video recorder, audio recorder, speaker, keypad, microphone, keyboard, switch, button, inferred transmitter and/or receiver, scanner, barcode scanner, thermocouple, or stylus.

13. A configurable housing for a personal electronic device comprising one or more thermoplastic polymers.

14. A configurable housing for a personal electronic device comprising a polycarbonate resin and an acrylonitrile, butadiene and styrene terpolymer blend (PC/ABS).

15. A method to prepare a configurable housing for a personal electronic device.
